(19) United States
(12) Patent Application Publication
(10) Pub. No.: US 2019/0226087 A1
(43) Pub. Date: Jul. 25, 2019

(54) HEATED CERAMIC FACEPLATE

(71) Applicant: Applied Materials, Inc., Santa Clara, CA (US)

(72) Inventors: Yuxing ZHANG, Santa Clara, CA (US); Kaushik ALAYAVALLI, Sunnyvale, CA (US); Kalyanjit GHOSH, San Jose, CA (US); Sanjeev BALUJA, Campbell, CA (US); Daniel HWUNG, Los Gatos, CA (US)

(21) Appl. No.: 16/254,806

(22) Filed: Jan. 23, 2019

Related U.S. Application Data
(60) Provisional application No. 62/621,413, filed on Jan. 24, 2018.

(51) Int. Cl. C23C 16/455

(52) U.S. Cl. CPC C23C 16/45559

(57) ABSTRACT

Embodiments herein relate to apparatus for gas distribution in a processing chamber. More specifically, aspects of the disclosure relate to a ceramic faceplate. The faceplate generally has a ceramic body. A recess is formed in an upper surface of the faceplate body. A plurality of apertures is formed in the recess through the faceplate. A heater is optionally disposed in the recess to heat the faceplate.

### CROSS-REFERENCE TO RELATED APPLICATIONS

This application claims benefit of U.S. provisional patent application Ser. No. 62/621,413, filed Jan. 24, 2018, which is herein incorporated by reference in its entirety.

### BACKGROUND

### Field

Embodiments of the present disclosure generally relate to a faceplate for use in processing chambers.

### Description of the Related Art

In the fabrication of integrated circuits, deposition processes such as chemical vapor deposition (CVD) or atomic layer deposition (ALD) are used to deposit films of various materials upon semiconductor substrates. In other operations, a layer altering process, such as etching, is used to expose a portion of a layer for further processing. Often, these processes are used in a repetitive fashion to fabricate various layers of an electronic device, such as a semiconductor device.

Fabricating a defect free semiconductor device is desirable when assembling an integrated circuit. Contaminants or defects present in a substrate or layers thereon can cause manufacturing defects within the fabricated device. For example, contaminants present in the processing chamber or the process gas delivery system may be deposited on the substrate causing defects and reliability issues in the semiconductor device fabricated. Accordingly, it is desirable to form a defect-free film when performing a deposition process. However, with conventional deposition devices, the layered films may be formed with defects and contaminants.

Therefore, what is needed in the art are improved apparatus for film deposition.

### SUMMARY

In one embodiment, a faceplate includes a body. The body has a top surface, a first bottom surface, and a second bottom surface. A third bottom surface extends between the first bottom surface and the second bottom surface. An outer surface extends between the top surface and the first bottom surface. A recess is formed in the top surface of the body and a plurality of apertures is formed between the recess and the second bottom surface. The body is formed from a ceramic material.

In another embodiment, a processing chamber includes a body. A substrate support is disposed within the body. A lid assembly is coupled to the body wherein the lid assembly has a lid, a blocker plate coupled to the lid, and a faceplate formed from a ceramic material coupled to the blocker plate and the body. The faceplate has a body wherein in the body has a top surface, a first bottom surface, a second bottom surface, and a third bottom surface extending between the first bottom surface and the second bottom surface. An outer surface extends between the top surface and the first bottom surface. A recess formed in the top surface of the faceplate body. A plurality of apertures is formed between the recess and the second bottom surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 illustrates a schematic arrangement of an exemplary process chamber according to one embodiment of the disclosure.

FIG. 2A illustrates a top-down view of a faceplate according to one embodiment of the disclosure.

FIG. 2B illustrates a sectional view of the faceplate of FIG. 2A.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein relate to apparatus for gas distribution in a processing chamber. More specifically, aspects of the disclosure relate to a ceramic faceplate. The faceplate generally has a ceramic body. A recess is formed in an upper surface of the faceplate body. A plurality of apertures is formed in the recess through the faceplate. A heater is optionally disposed in the recess to heat the faceplate.

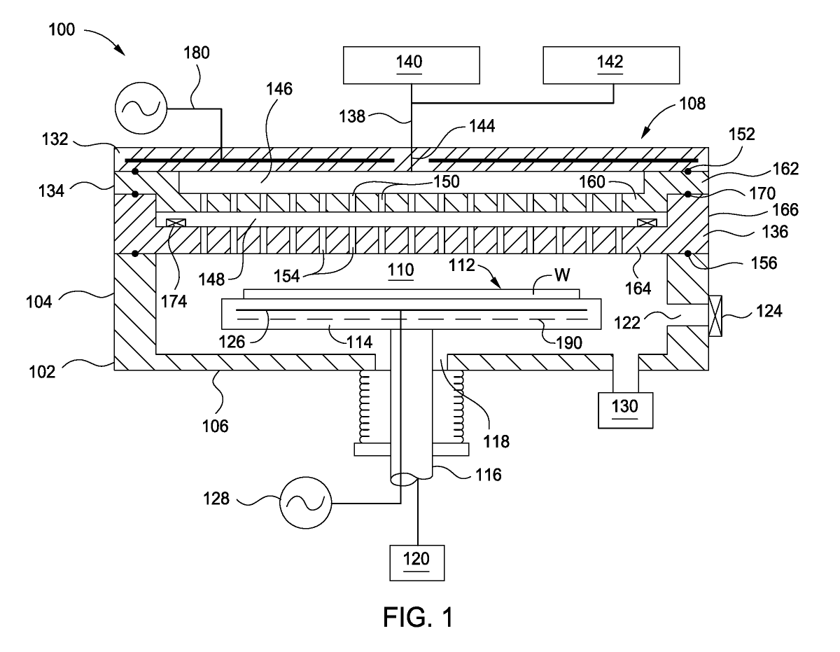

FIG. 1 illustrates a schematic arrangement of an exemplary process chamber 100 according to one embodiment. The process chamber 100 includes a body 102 having a sidewall 104 and base 106. A lid assembly 108 couples to the body 102 to define a process volume 110 therein. In one embodiment, the body 102 is formed from a metal, such as aluminum or stainless steel, but any material suitable for use with processing therein may be utilized. A substrate support 112 is disposed within the process volume 110 and supports a substrate W during processing within the process chamber 100. The substrate support 112 includes a support body 114 coupled to a shaft 116. The shaft 116 is coupled to the support body 114 and extends out of the body 102 through an opening 118 in the base 106. The shaft 116 is coupled to an actuator 120 to vertically move the shaft 116, and the support body 114 coupled thereto, between a substrate loading position and a substrate processing position. A vacuum system 130 is fluidly coupled to the process volume 110 in order to evacuate gases from the process volume 110.

To facilitate processing of a substrate W in the process chamber 100, the substrate W is disposed on the support body 114, opposite of the shaft 116. A port 122 is formed in the sidewall 104 to facilitate ingress and egress of the substrate W into the process volume 110. A door 124, such as a slit valve, is actuated to selectively allow the substrate W to pass through the port 122 to be loaded onto, or removed from, the substrate support 112. An electrode 126 is optionally disposed within the support body 114 and electrically coupled to a power source 128 through the shaft 116. The electrode 126 is selectively biased by the power source 128 to create an electromagnetic field to chuck the substrate W to the support body 114 and/or to facilitate plasma generation or control. In certain embodiments, a heater 190, such as a resistive heater, is disposed within the support body 114 to heat the substrate W disposed thereon.

The lid assembly 108 includes a lid 132, a blocker plate 134, and a faceplate 136. The blocker plate 134 includes a recessed circular distribution portion 160 surrounded by an annular extension 162. The blocker plate 134 is disposed between the lid 132 and the faceplate 136 and coupled to each of the lid 132 and the faceplate 136 at the annular extension 162. The lid 132 couples to the annular extension 162 opposite the body 102. The faceplate 136 couples to the annular extension 162. A first volume 146 is defined between the blocker plate 134 and the lid 132. A second volume 148 is further defined between the blocker plate 134 and the faceplate 136. A plurality of apertures 150 are formed through the distribution portion 160 of the blocker plate 134 and facilitate fluid communication between the first volume 146 and the second volume 148.

An inlet port 144 is disposed within the lid 132. The inlet port 144 is coupled to a gas conduit 138. The gas conduit 138 allows a gas to flow from a first gas source 140, such as a process gas source, through the inlet port 144 into the first volume 146. A second gas source 142, such as a cleaning gas source, is optionally coupled to the gas conduit 138.

The first gas source 140 supplies a process gas, such as an etching gas or a deposition gas, to the process volume 110 to etch or deposit a layer on the substrate W. The second gas source 142 supplies a cleaning gas to the process volume 110 in order to remove particle depositions from internal surfaces of the process chamber 100. To facilitate processing of a substrate, an RF generator 180 is optionally coupled to the lid 132 to excite a gas from the first gas source 140, the second gas source 142, or both the first gas source 140 and the second gas source 142 to form an ionized species. A seal 152, such as an O-ring, is disposed between the blocker plate 134 and the lid 132 at the annular extension 162 surrounding the first volume 146 in order to isolate the process volume 110 from the external environment, allowing maintenance of a vacuum therein.

The faceplate 136 has a distribution portion 164 and a coupling portion 166 disposed radially outward of the distribution portion 164. The distribution portion 164 is disposed between the process volume 110 and the second volume 148. The coupling portion 166 surrounds the distribution portion 164 at a periphery of the faceplate 136. In one embodiment, the faceplate 136 is formed of a ceramic material such as alumina or aluminum nitride. However, other materials, such as aluminum oxide, yttria, and other suitable ceramic materials are contemplated.

Apertures 154 are disposed through the faceplate 136 within the distribution portion 164. The apertures 154 allow fluid communication between the process volume 110 and the second volume 148. During operation, a gas is permitted to flow from the inlet port 144 into the first volume 146, through apertures 150 in the blocker plate 134, and into the second volume 148. From the second volume 148, the gas flows through the apertures 154 in the faceplate 136 into the process volume 110. The arrangement and sizing of the apertures 154 allow the selective flow of the gas into the process volume 110 in order to achieve desired gas distribution. For example, a uniform distribution across the substrate W may be desired for certain processes.

One or more heaters 174 are disposed on the faceplate 136. In one embodiment, the heaters 174 are disposed within the faceplate 136. The heaters 174 may be any mechanism capable of providing heat to the faceplate 136. In one embodiment, the heaters 174 include a resistive heater, which may be embedded within and encircling the faceplate 136. In another embodiment, the heaters 174 include a channel (not shown) formed in the faceplate 136 that flows a heated fluid therethrough. The heaters 174 heat the faceplate 136 to a high temperature, for example, 300 F, 400 F, 500 F, or higher. Increasing the temperature of the faceplate 136 to a temperature such as 300 F, 400 F, or 500 F during processing, such as during a chemical vapor deposition process, results in significantly less contaminant particle deposition on the substrate W.

A seal 170 is disposed between the faceplate 136 and the blocker plate 134 to allow maintenance of a vacuum within the process volume 110. A second seal 156 is disposed between the faceplate 136 and the sidewall 104. In the embodiment of FIG. 1, the seals 156, 170 are O-rings formed from materials such as polytetrafluoroethylene (PTFE), rubber, or silicone. Other seal designs, such as sheet gaskets or bonds, are also contemplated. In conventional designs, a faceplate is generally not heated to the high temperatures described herein (e.g., such as about 300 F, 400 F, or 500 F) because the sealing materials degrade at elevated temperatures, such as 250 F or above. However, by utilizing the ceramic faceplate 136 as described herein, the ceramic material of the faceplate 136 limits conduction of heat provided by the heaters 174 from an area of the faceplate 136 proximate the distribution portion 164 to the coupling portion 166 having seals 156, 170 therein. Accordingly, an inner portion of faceplate 136 proximate to process volume 110 may be heated to elevated temperatures while an outer portion, adjacent to seals 156, 170, is maintained at a lower temperature. This limits contaminant particle disposition on the substrate W being processed while also protecting the seals 156, 170 from thermal degradation. Therefore, a seal is maintained around the process volume 110 while the faceplate 136 is heated to high temperatures.

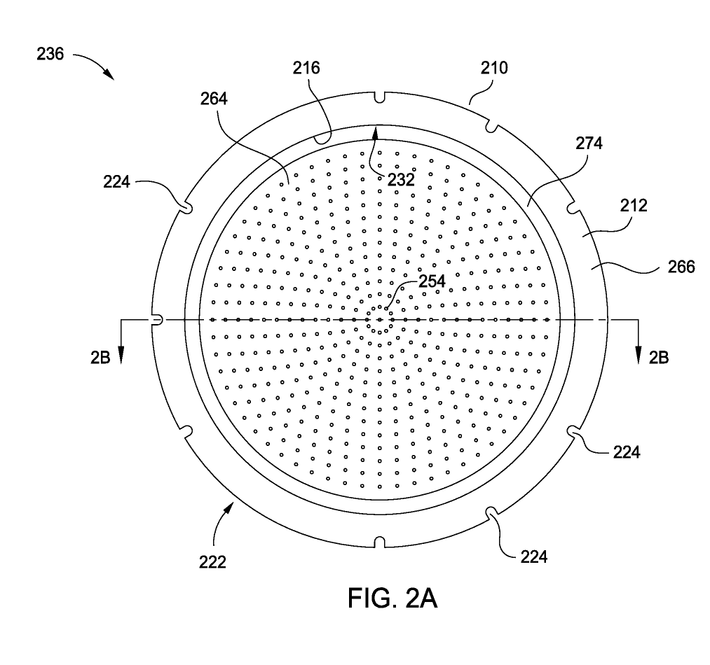

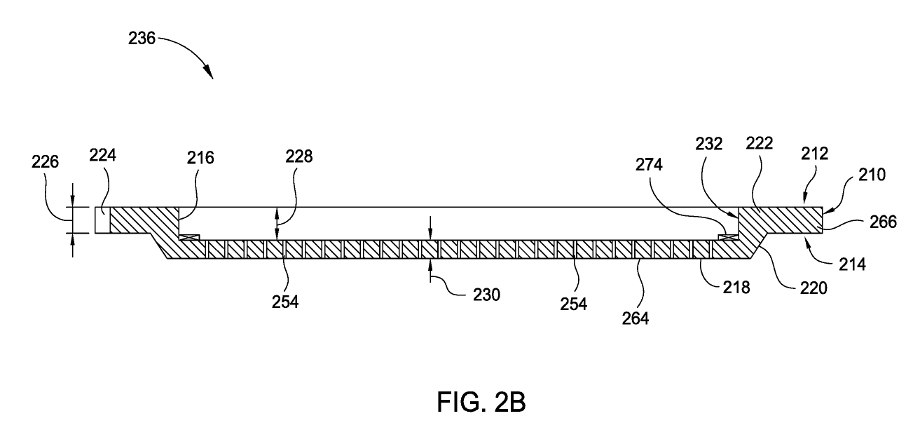

FIG. 2A illustrates a plan view of a faceplate 236. FIG. 2B is a section view of the faceplate 236 of FIG. 2A along the indicated section line 2B-2B. FIGS. 2A and 2B are described concurrently for clarity. The faceplate 236 may be used in place of the faceplate 136 of FIG. 1. The faceplate 236 has a body 222 defined by an upper surface 212, a first lower surface 214, a second lower surface 218, and an outer surface 210 extending between, and coupling, the upper surface 212 and the first lower surface 214. A third lower surface 220 extends linearly, in a radially outward and representatively upward direction, from the second lower surface 218 to the first lower surface 214. The third lower surface 220 is non-perpendicular to the first lower surface 214 and the second lower surface 218. In one example, the first lower surface 214, the second lower surface 218, and the first upper surface 212 are parallel to one another and each disposed in different planes. In such an example, the outer surface 210 is perpendicular to each of the first lower surface 214, the second lower surface 218, and the first upper surface 212.

A recess 216 is formed in the upper surface 212. The recess 216 is formed by a counter bore in the body 222, and in the illustrated example, has a circular shape. A distribution portion 264 of the body 222 is defined radially inward of a wall 232 of the recess 216. In one example, the wall 232 is parallel to the outer surface 210, and has a height greater than a height of the outer surface 210. A coupling portion 266 is defined radially outward of the recess 216, and is represented as a circular flanged portion of the body 222. A plurality of apertures 254 are formed in the distribution portion 264 extending between the recess 216 (e.g., an upper surface of the distribution portion 264) and the second lower surface 218. In such an example, the upper surface of the distribution portion 264 is positioned in a plane below a plane of the first lower surface 214 in the illustrated view. In the embodiment of FIGS. 2A and 2B, the apertures 254 are arranged in sets of concentric circles of apertures disposed around a central axis of the faceplate 236. However, it is to be understood that other arrangements of apertures 254 may be utilized herewith to effect desired gas flow and distribution therethrough.

A heater 274 is disposed in the recess 216 surrounding the apertures 254. The heater 274 may be any mechanism capable of providing heat to the faceplate 136. In one embodiment, the heater 274 is a resistive heater, which may be embedded within and encircling the faceplate 136. In another embodiment, the heater 274 is a channel (not shown) formed in the faceplate 236 that flows a heated fluid therethrough.

A plurality of alignment features 224 are formed in the outer surface 210. In FIGS. 2A and 2B, the alignment features 224 are slots extending through the body 222 between the upper surface 212 and the first lower surface 214. The alignment features 224 may be evenly or unevenly distributed about a central axis of the faceplate 236.

The body 222 has a thickness 226 between the upper surface 212 and the first lower surface 214. The body 222 also has a thickness 230 between the bottom of the recess 216 and the second lower surface 218. The thicknesses 226, 230 are generally minimized in order to improve manufacturing quality of the faceplate. For example, the thickness 230 is minimized so the apertures 254 may be formed therethrough, such as by drilling, without causing damage to the body 222. The thicknesses 226, 230 may also be minimized to reduce the cross-sectional area through which heat provided by the heater 276 to the distribution portion 264 is convected to the coupling portion 266. The thicknesses 226, 230 may be, for example, between about ⅛ inch and about 1 inch, such as about ¼ inch and about ¾ inch. For example, the thicknesses 226, 230 may be about ½ inch.

The recess 216 also has a depth 228 between a bottom surface thereof and a plane defined by the upper surface 212. The depth 228 is sized to allow sufficient gas distribution throughout the recess 216. The depth 228 is also sized to prevent formation of a plasma therein when the faceplate 236 is utilized with a RF generator, such as RF generator 180 of FIG. 1. By minimizing the depth 228 of the recess 216, a remote field current generated by the RF generator does not couple to a gas in the volume defined by the recess 216 but passes therethrough to couple with a gas within a processing volume, such as process volume 110 of FIG. 1. For example, the depth 228 may be about 300 microns to about 700 microns, such as about 400 microns to about 600 microns. For example, the depth 228 may be about 500 microns.

The embodiments described herein advantageously reduce the deposition of contaminant particles on a substrate. The ceramic faceplate allows the temperature of the faceplate to be increased to a high temperature, thus limiting the deposition of contaminant particles while maintaining the sealing capabilities of the outboard disposed seals.

While the foregoing is directed to embodiments of the present disclosure, other and further embodiments of the disclosure may be devised without departing from the basic scope thereof, and the scope thereof is determined by the claims that follow.

What is claimed is:

1. A faceplate for processing substrate, comprising:
a body formed from a ceramic material, the body comprising:
a top surface;
a first bottom surface;
a second bottom surface;
a third bottom surface extending between the first bottom surface and the second bottom surface; and
an outer surface extending between the top surface and the first bottom surface;
a recess formed in the top surface; and
a plurality of apertures formed between the recess and the second bottom surface.

2. The faceplate of claim 1, further comprising a heater disposed within the recess.

3. The faceplate of claim 1, wherein a depth of the recess is about 500 microns.

4. The faceplate of claim 1, further comprising a plurality of alignment features formed in the outer surface disposed about a central axis of the faceplate.

5. The faceplate of claim 4, wherein the plurality of alignment features comprise slots between the top surface and the first bottom surface.

6. The faceplate of claim 1, wherein the ceramic material is alumina or aluminum nitride.

7. The faceplate of claim 1, wherein the third bottom surface extends linearly between the first bottom surface and the second bottom surface in a radially outward direction towards the top surface.

8. A processing chamber, comprising:
a chamber body;
a substrate support disposed within the chamber body; and
a lid assembly coupled to the chamber body, the lid assembly comprising:
a lid;
a blocker plate coupled to the lid; and
a faceplate formed from a ceramic material coupled to the blocker plate and the chamber body, the faceplate comprising:
a faceplate body, the faceplate body comprising:
a top surface;
a first bottom surface;
a second bottom surface;
a third bottom surface extending between the first bottom surface and the second bottom surface; and
an outer surface extending between the top surface and the first bottom surface;
a recess formed in the top surface of the faceplate body; and
a plurality of apertures formed between the recess and the second bottom surface.

9. The processing chamber of claim 8, further comprising a heater disposed within the recess of the faceplate.

10. The processing chamber of claim 8, wherein a depth of the recess is about 400 microns to about 600 microns.

11. The processing chamber of claim 8, further comprising a plurality of alignment features formed in the outer surface disposed about a central axis of the faceplate.

12. The processing chamber of claim 11, wherein the alignment features comprise slots between the top surface and the first bottom surface.

13. The processing chamber of claim 8, wherein the ceramic material is alumina or aluminum nitride.

14. The processing chamber of claim 8, wherein the third bottom surface extends linearly between the first bottom surface and the second bottom surface in a radially outward direction towards the top surface.

15. A lid assembly for a processing a substrate, comprising:
a lid;
a blocker plate coupled to the lid to define a first volume, the blocker plate having a recessed distribution portion surrounded by an annular extension, the distribution portion having a first plurality of apertures formed therethrough;
a faceplate coupled to the annular extension to define a second volume, the faceplate having a distribution portion and a coupling portion disposed radially outward of the distribution portion, the faceplate further comprising:
a faceplate body, the faceplate body comprising:
a top surface;
a first lower surface;
a second lower surface;
a third lower surface; and
an outer surface;
a recess formed in the top surface of the faceplate body; and
a second plurality of apertures formed between the recess and the second lower surface.

16. The lid assembly of claim 15, further comprising a heater disposed on the faceplate.

17. The lid assembly of claim 15, wherein the faceplate is formed of a ceramic material.

18. The lid assembly of claim 17, wherein the ceramic material is alumina or aluminum nitride.

19. The lid assembly of claim 15, wherein a depth of the recess is about 500 microns.

20. The lid assembly of claim 15, wherein the third lower surface extends radially outward from the second lower surface and the first lower surface at a non-perpendicular angle.
